(19) United States
(12) Patent Application Publication
(10) Pub. No.: US 2023/0091748 A1
(43) Pub. Date: Mar. 23, 2023

(54) DETECTION DEVICE AND DETECTION METHOD

(71) Applicant: Shenzhen China Star Optoelectronics Semiconductor Display Technology Co., Ltd., Shenzhen, Guangdong (CN)

(72) Inventor: Bo HE, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/962,284

(22) PCT Filed: May 9, 2020
(86) PCT No.: PCT/CN2020/089482

§ 371 Date: Jul. 15, 2020

(30) Foreign Application Priority Data
Apr. 22, 2020 (CN) 202010323020.8

(51) Int. Cl. G01R 31/26; G01M 11/02

(52) U.S. Cl. CPC G01R 31/2635; G01M 11/0207

(57) ABSTRACT

A detection device and a detection method are provided. The detection device includes a plurality of detection portions, a signal generator, and an optical component. The detection portions include a first detection electrode and a second detection electrode disposed at a same side. Different electrical signals provided by the signal generator are provided to a first electrode and a second detection electrode of a corresponding micro light-emitting device by the first detection electrode and the second detection electrode, respectively, to make a plurality of micro light-emitting devices emit light, and corresponding optical parameters are obtained by the optical component according to light-emitting conditions.

### TECHNICAL FIELD

The present application relates to a display technology field, in particular to a technology field for manufacturing a display panel, and specifically relates to a detection device and a detection method.

### BACKGROUND

Micro light-emitting diode (micro LED) technology is a technology in which LED arrays with high-density and small-size are integrated on one chip. A micro LED display panel prepared by using this technology has advantages of high brightness, high color gamut, and high resolution.

However, since there is a large number of micro LED chips in the micro LED display panel, and a size of each of the micro LED chips is extremely small, it is difficult to quickly and accurately perform electroluminescence detection on all of the micro LED chips to calculate a yield of the micro LED chips in the micro LED display panel.

In summary, it is necessary to provide a detection device and a detection method that can be used to quickly and accurately perform electroluminescence detection on all of the micro LED chips in the micro LED display panel.

### TECHNICAL PROBLEM

Embodiments of the present application provide a detection device and a detection method. A first detection electrode and a second detection electrode of each detection portion in the detection device are electrically connected to a first electrode and a second electrode of a corresponding micro light-emitting device, respectively. By using a plurality of detection portions to simultaneously perform electroluminescence detection on a plurality of micro light-emitting devices, a problem in the prior art of difficulty in quickly and accurately performing electroluminescence detection on all micro light-emitting diode (LED) chips in a micro LED display panel is solved.

### TECHNICAL SOLUTION

An embodiment of the present application provides a detection device configured to perform electroluminescence detection on a plurality of micro light-emitting devices, wherein each of the plurality of micro light-emitting devices comprises a first electrode and a second electrode disposed at a same side, and the detection device comprises:
a substrate; and
a plurality of detection portions disposed on the substrate and configured to perform electroluminescence detection on the plurality of micro light-emitting devices, wherein each of the plurality of detection portions comprises a first detection electrode and a second detection electrode disposed at a same side, the first detection electrode of each of the plurality of detection portions is disposed opposite to the first electrode of a corresponding micro light-emitting device, the second detection electrode of each of the plurality of detection portions is disposed opposite to the second electrode of a corresponding micro light-emitting device, when the plurality of detection portions perform electroluminescence detection on the plurality of micro light-emitting devices, the first detection electrode of each of the plurality of detection portions is electrically connected to the first electrode of the corresponding micro light-emitting device by contact, the second detection electrode of each of the plurality of detection portions is electrically connected to the second electrode of the corresponding micro light-emitting device by contact, and each of the plurality of detection portions comprises:
a pad disposed between the substrate and a corresponding first detection electrode, and disposed between the substrate and a corresponding second detection electrode, and configured to raise height of the corresponding first detection electrode and the corresponding second detection electrode;
a signal generator providing different electrical signals to the first detection electrode and the second detection electrode of each of the plurality of detection portions when the detection device performs electroluminescence detection on the plurality of micro light-emitting devices, to make the plurality of micro light-emitting devices emit light;
an optical component located on at least one side of the plurality of micro light-emitting devices and configured to obtain optical parameters of the plurality of micro light-emitting devices according to light-emitting conditions of the plurality of micro light-emitting devices.

In one embodiment, a gap is defined between the first detection electrode and the second detection electrode of each of the plurality detection portions to insulate the first detection electrode and the second detection electrode of each of the plurality of detection portions.

In one embodiment, a barrier is disposed in the gap to insulate the first detection electrode and the second detection electrode of each of the plurality of detection portions.

In one embodiment, each of the plurality of detection portions further comprises:
a first insulation portion disposed in a first insulation area on the corresponding first detection electrode, wherein the first insulation area is located away from the corresponding second detection electrode; and
a second insulation portion disposed in a second insulation area on the corresponding second detection electrode, wherein the second insulation area is located away from the corresponding first detection electrode.

In one embodiment, the first detection electrodes and the second detection electrodes of two adjacent detection portions located in a same row of the plurality of detection portions are arranged in reverse order, two first detection electrodes close to each other are integrally formed in the two adjacent detection portions located in the same row of the plurality of detection portions, and two second detection electrodes close to each other are integrally formed in the two adjacent detection portions located in the same row of the plurality of detection portions.

In one embodiment, a transparent material is a constituent material of the substrate.

An embodiment of the present application further provides a detection device configured to perform electroluminescence detection on a plurality of micro light-emitting devices, wherein each of the plurality of micro light-emitting devices comprises a first electrode and a second electrode disposed at a same side, and the detection device comprises:
a substrate; and
a plurality of detection portions, disposed on the substrate and configured to perform electroluminescence detection on the plurality of micro light-emitting devices, wherein each of the plurality of detection portions comprises a first detection electrode and a second detection electrode disposed at a same side, when the plurality of detection portions perform electroluminescence detection on the plurality of micro light-emitting devices, the first detection electrode of each of the plurality of detection portions is electrically connected to the first electrode of a corresponding micro light-emitting device by contact, and the second detection electrode of each of the plurality of detection portions is electrically connected to the second electrode of a corresponding micro light-emitting device by contact;
a signal generator providing different electrical signals to the first detection electrode and the second detection electrode of each of the plurality of detection portions when the detection device performs electroluminescence detection on the plurality of micro light-emitting devices, to make the plurality of micro light-emitting devices emit light; and
an optical component located on at least one side of the plurality of micro light-emitting devices and configured to obtain optical parameters of the plurality of micro light-emitting devices according to light-emitting conditions of the plurality of micro light-emitting devices.

In one embodiment, the first detection electrode of each of the plurality of detection portions is disposed opposite to the first electrode of the corresponding micro light-emitting device, and the second detection electrode of each of the plurality of detection portions is disposed opposite to the second electrode of the corresponding micro light-emitting device.

In one embodiment, a gap is defined between the first detection electrode and the second detection electrode of each of the plurality detection portions to insulate the first detection electrode and the second detection electrode of each of the plurality of detection portions.

In one embodiment, a barrier is disposed in the gap to insulate the first detection electrode and the second detection electrode of each of the plurality of detection portions.

In one embodiment, each of the plurality of detection portions further comprises:
a pad disposed between the substrate and a corresponding first detection electrode, and disposed between the substrate and a corresponding second detection electrode, and configured to raise height of the corresponding first detection electrode and the corresponding second detection electrode.

In one embodiment, each of the plurality of detection portions further comprises:
a first insulation portion disposed in a first insulation area on a corresponding first detection electrode, wherein the first insulation area is located away from a corresponding second detection electrode; and
a second insulation portion disposed in a second insulation area on the corresponding second detection electrode, wherein the second insulation area is located away from the corresponding first detection electrode.

In one embodiment, the first detection electrodes and the second detection electrodes of two adjacent detection portions located in a same row of the plurality of detection portions are arranged in reverse order, two first detection electrodes close to each other are integrally formed in the two adjacent detection portions located in the same row of the plurality of detection portions, and two second detection electrodes close to each other are integrally formed in the two adjacent detection portions located in the same row of the plurality of detection portions.

In one embodiment, a transparent material is a constituent material of the substrate.

An embodiment of the present application further provides a detection method configured to perform electroluminescence detection on a plurality of micro light-emitting devices, wherein each of the plurality of micro light-emitting devices comprises a first electrode and a second electrode disposed at a same side, and the detection method comprises following steps:
providing the plurality of micro light-emitting devices and a detection device, wherein the detection device comprises a substrate and a plurality of detection portions disposed on the substrate, the plurality of detection portions are configured to perform electroluminescence detection on the plurality of micro light-emitting devices, and each of the plurality of detection portions comprises a first detection electrode and a second detection electrode;
electrically connecting the first detection electrode of each of the plurality of detection portions to the first electrode of a corresponding micro light-emitting device and electrically connecting the second detection electrode of each of the plurality of detection portions to the second electrode of the corresponding micro light-emitting device;
providing different electrical signals to the first detection electrode and the second detection electrode of each of the plurality of detection portions to make the plurality of micro light-emitting devices emit light; and
obtaining optical parameters of the plurality of micro light-emitting devices according to light-emitting conditions of the plurality of micro light-emitting devices.

In one embodiment, the step of electrically connecting the first detection electrode of each of the plurality of detection portions to the first electrode of the corresponding micro light-emitting device and electrically connecting the second detection electrode of each of the plurality of detection portions to the second electrode of the corresponding micro light-emitting device comprises steps of:
arranging the plurality of micro light-emitting devices in an array to make the plurality of micro light-emitting devices correspond to the plurality of detection portions one by one, to make the first electrode of each of the plurality of micro light-emitting devices be disposed opposite to the first detection electrode of a corresponding detection portion, and to make the second electrode of each of the plurality of micro light-emitting devices be disposed opposite to the second detection electrode of the corresponding detection portion; and
making the detection device be disposed close to the plurality of micro light-emitting devices arranged in the array to electrically connect the first detection electrode of each of the plurality of detection portions to the first electrode of the corresponding micro light-emitting device, and electrically connect the second detection electrode of each of the plurality of detection portions to the second electrode of the corresponding micro light-emitting device.

### BENEFICIAL EFFECT

A beneficial effect of the present application is: a detection device and a detection method are provided by embodiments of the present application. Each of a plurality of detection portions includes a first detection electrode and a second detection electrode disposed at a same side. Different electrical signals are provided to the first detection electrode and the second detection electrode of each of the detection portions by a signal generator. The first detection electrode and the second detection electrode of each of the detection portions are electrically connected to the first electrode and the second electrode of a corresponding micro light-emitting device, respectively, to make a plurality of micro light-emitting devices emit light, and corresponding optical parameters are obtained by an optical component according to light-emitting conditions of the plurality of micro light-emitting devices. In the present solution, the first detection electrode and the second detection electrode of each of the detection portions in the detection device are electrically connected to the first electrode and the second electrode of the corresponding micro light-emitting device, respectively, and electroluminescence detection may be accurately performed on the plurality of micro light-emitting devices at one time by the detection device to improve rate and accuracy of electroluminescence detection performed on the plurality of micro light-emitting devices.

### DESCRIPTION OF DRAWINGS

The present invention is further described below with reference to appending drawings. It should be explained that the drawings in the following description are merely some embodiments for explaining the present invention. For persons skilled in this art, other drawings can be obtained from these drawings under the premise of no creative efforts made.

FIG. 1 is a schematic diagram showing an application scenario of a detection device according to an embodiment of the present invention.

FIG. 2 is a schematic diagram showing a three-dimensional structure of a micro light-emitting device according to an embodiment of the present invention.

FIG. 3 is a schematic diagram showing a three-dimensional structure of a detection portion according to an embodiment of the present invention.

FIG. 4 is a schematic diagram showing a three-dimensional structure of another detection portion according to an embodiment of the present invention.

FIG. 5 is a schematic diagram showing a three-dimensional structure of a detection device according to an embodiment of the present invention.

FIG. 6 is a flowchart of a detection method according to an embodiment of the present invention.

FIG. 7 is a flowchart of another detection method according to an embodiment of the present invention.

### DETAILED DESCRIPTION OF PREFERRED EMBODIMENTS

Technical solutions in embodiments of the present application will be described clearly and completely below in conjunction with drawings in the embodiments of the present application. Obviously, the described embodiments are only parts of embodiments of the present application, not all of the embodiments. Based on the embodiments of the present application, all other embodiments obtained by persons skilled in this art under the premise of no creative efforts made belong to a protection scope of the present application.

In a description of the present invention, it should be understood that terms such as “upper”, “same side”, “row”, “close”, “away” are indicated orientations or directions with referring to the accompanying drawings. Wherein, for example, “upper” refers to a surface above an object, specifically refers to directly above, diagonally above, upper surface, as long as higher than the upper surface of the object, the orientations or directions are only used for describing the present invention and illustrating briefly, which does not indicate or imply that referred equipment or devices must have a specific orientation to construct and operate with the specific orientation, so that it cannot be understood as a limitation to the present invention.

In addition, it should be noted that the drawings only provide structures and steps that are closely related to the present invention, and omit some details that are not related to the invention to simplify the drawings and make the invention clear to understand fully at one glance. It does not mean that an actual device and method are exactly same as the drawings, and should not be regarded as a limitation of the actual device and method.

The present invention provides a detection device that includes, but is not limited to, the following embodiments.

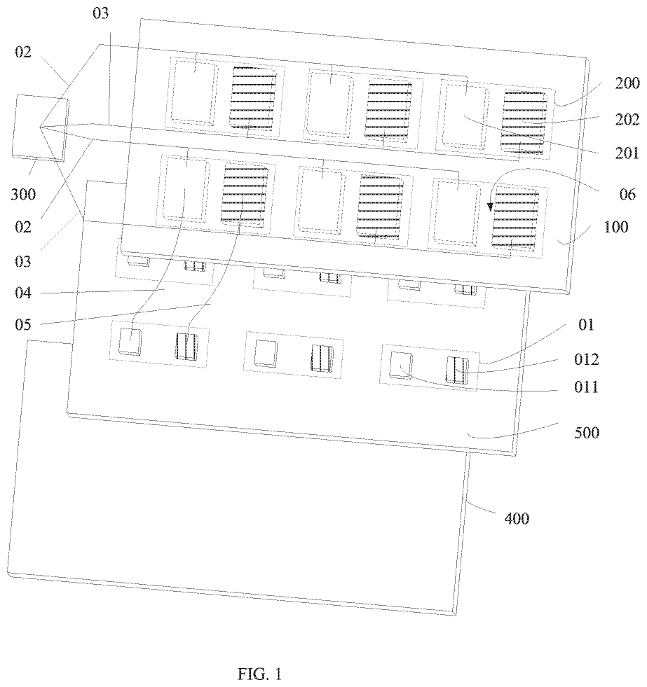

In one embodiment, as shown in FIG. 1, the detection device is configured to perform electroluminescence detection on a plurality of micro light-emitting devices 01. Each of the plurality of micro light-emitting devices 01 includes a first electrode 011 and second electrode 012 disposed at a same side. The detection device includes: a substrate 100; a plurality of detection portions 200 disposed on the substrate 100, wherein the plurality of detection portions 200 are configured to perform electroluminescence detection on the plurality of micro light-emitting devices 01, each of the plurality of detection portions 200 includes a first detection electrode 201 and a second detection electrode 202 disposed at a same side, and when the plurality of detection portions 200 perform electroluminescence detection on the plurality of micro light-emitting devices 01, the first detection electrode 201 of each of the plurality of detection portions 200 is electrically connected to the first electrode 011 of a corresponding micro light-emitting device 01, and the second detection electrode 202 of each of the plurality of detection portions 200 is electrically connected to the second electrode 012 of a corresponding micro light-emitting device 01; a signal generator 300, wherein when the detection device performs electroluminescence detection on the plurality of micro light-emitting devices 01, the signal generator 300 provides different electrical signals to the first detection electrode 201 and the second detection electrode 202 of each of the plurality of detection portions 200 to make the plurality of micro light-emitting devices 01 emit light; an optical component 400, located on at least one side of the plurality of micro light-emitting devices 01 and configured to obtain optical parameters of the plurality of micro light-emitting devices 01 according to light-emitting conditions of the plurality of micro light-emitting devices 01.

In one embodiment, a transparent material may be a constituent material of the substrate 100. For example, the substrate 100 may be a transparent glass, or the constituent material of the substrate 100 may be a colorless material. Further, the optical component 400 may be located at one side of the substrate 100 away from the plurality of micro light-emitting devices 01, and light emitted by the plurality of micro light-emitting devices 01 may pass through the substrate 100 to facilitate the optical component 400 to perform detection.

Based on this, transparent conductive materials may be constituent materials of the first detection electrode 201 and the second detection electrode 202. For example, essence of the first detection electrode 201 and the second detection electrode 202 may be a strip electrode made of indium-tin-oxide. Similarly, the optical component 400 may be located at one side of the substrate 100 away from the plurality of micro light-emitting devices 01, and light emitted by the plurality of micro light-emitting devices 01 may sequentially pass through the substrate 100, the first detection electrode 201, and the second detection electrode 202 to facilitate the optical component 400 to perform detection.

In particular, the plurality of micro light-emitting devices 01 may be arranged in an array on a base substrate 500 to fix the plurality of micro light-emitting devices 01 to facilitate the plurality of micro light-emitting devices 01 to align with the plurality of detection portions 200. Specifically, the base substrate 500 may be a transparent base substrate, such as a sapphire base substrate or a plastic base substrate. Based on this, the optical component 400 may be located at one side of the base substrate 500 away from the plurality of micro light-emitting devices 01, and light emitted by the plurality of micro light-emitting devices 01 may pass through the base substrate 500 to facilitate the optical component 400 to perform detection.

Specifically, when the plurality of detection portions 200 perform electroluminescence detection on the plurality of micro light-emitting devices 01, the signal generator 300 is electrically connected to the first detection electrode 201 of each of the plurality of detection portions 200 located in a same row by a first wire 02, and is electrically connected to the second detection electrode 202 of each of the plurality of detection portions 200 located in a same row by a second wire 03. Further, the first detection electrode 201 of each of the plurality of detection portions 200 located in a same row may be electrically connected to the first wire 02 through a wire, and the second detection electrode 202 of each of the plurality of detection portions 200 located in a same row may be electrically connected to the second wire 03 through a wire. Accordingly, the number of wires may be reduced to prevent interference between the wires.

Wherein, when the plurality of detection portions 200 perform electroluminescence detection on the plurality of micro light-emitting devices 01, the first detection electrode 201 of each of the plurality of detection portions 200 may be electrically connected to the first electrode 011 of the corresponding micro light-emitting device 01 by a third wire 04, and the second detection electrode 202 of each of the plurality of detection portions 200 may be electrically connected to the second electrode 012 of the corresponding micro light-emitting device 01 by a fourth wire 05; the signal generator 300 transmits a first voltage to the first electrode 011 of the corresponding micro light-emitting device 01 by the first wire 02 and the third wire 04 in sequence, and transmits a second voltage to the second electrode 012 of the corresponding micro light-emitting device 01 by the second wire 03 and the fourth wire 05 in sequence, to make the first electrode 011 and the second electrode 012 of each of the micro light-emitting devices 01 have the first voltage and the second voltage, respectively.

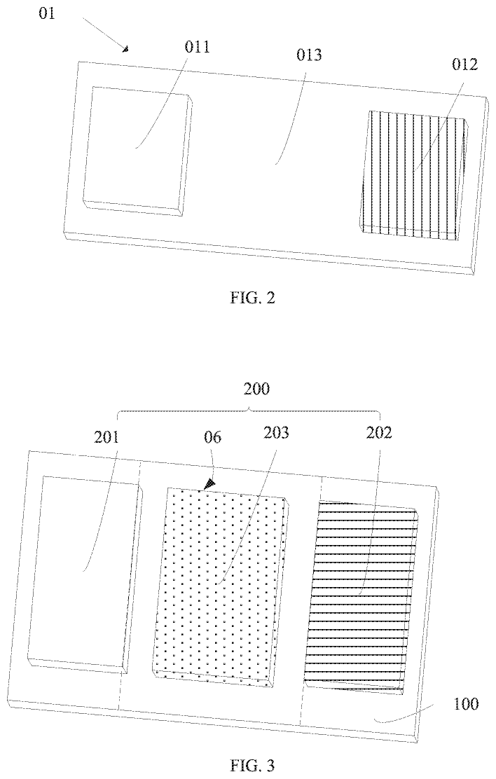

Specifically, as shown in FIG. 2, each of the micro light-emitting devices 01 further includes an epitaxial layer 013 disposed at one side of the first electrode 011 and the second electrode 012. Constituent materials of the first electrode 011 and the second electrode 012 may include a p-type doped phosphor material and an n-type doped phosphor material, respectively, and a constituent material of the epitaxial layer 013 may include nitrogen-gallium. When the first electrodes 011 and the second electrodes 012 of the micro light-emitting devices 01 have the first voltage and the second voltage, respectively, electrons and holes recombine to release energy to make the micro light-emitting devices 01 emit light.

It can be understood that the plurality of detection portions 200 of the detection device correspond to the plurality of micro light-emitting devices 01 one by one in number, that is, each of the detection portions 200 detects the corresponding micro light-emitting device 01. When the first voltage and the second voltage are provided to the plurality of micro light-emitting devices 01 by the signal generator 300, the working-normally micro light-emitting devices 01 will simultaneously emit light that meets the optical conditions at the same time. That is, it may detect whether functions of the plurality of micro light-emitting devices 01 are normal through light-emitting conditions of the plurality of micro light-emitting devices 01 at one time. Moreover, each of the detection portions 200 of the detection device is electrically connected to the corresponding micro light-emitting device 01 to ensure that each of the micro light-emitting devices 01 is only electrically connected to one detection portion 200, and ensure detection results are also accurate.

In one embodiment, as shown in FIG. 1, the first detection electrode 201 of each of the plurality of detection portions 200 is disposed opposite to the first electrode 011 of the corresponding micro light-emitting device 01, and the second detection electrode 202 of each of the plurality of detection portions 200 is disposed opposite to the second electrode 012 of the corresponding micro light-emitting device 01. It can be understood that the substrate 100 may be disposed close to the plurality of micro light-emitting devices 01, so that the first detection electrode 201 and the second detection electrode 202 of each of the plurality of detection portions 200 are in contact with the first electrode 011 and second electrode 012 of the corresponding micro light-emitting device 01, respectively. In a direct contact manner, the first detection electrode 201 is electrically connected to the corresponding first electrode 011, and the second detection electrode 202 is electrically connected to the corresponding second electrode 012. Further, it may make certain pressures exist between the first detection electrode 201 and the second detection electrode 202 of each of the detection portions 200 and the first electrode 011 and the second electrode 012 of the corresponding micro light-emitting device 01, respectively, to ensure complete electrical connection. Accordingly, the third wire 04 and the fourth wire 05 can be omitted, and a risk of disconnection between the first detection electrode 201 and the second detection electrode 202 and the corresponding first electrode 011 and second electrode 012 is reduced, respectively.

It should be noted that when the first detection electrode 201 of each of the plurality of detection portions 200 is disposed opposite to the first electrode 011 of the corresponding micro light-emitting device 01, the plurality of detection portions 200 of the detection device do not need to correspond to the plurality of micro light-emitting devices 01 one by one in number, and the number of the plurality of detection portions 200 may be less than the number of the plurality of micro light-emitting devices 01. For example, when the plurality of micro light-emitting device 01 are arranged in “40*40” arrays, the plurality of detection portions 200 may be arranged in “20*20” arrays, and “20*20” arrays located at upper-left corners, “20*20” arrays located at upper-right corners, “20*20” arrays located at lower-left corners, and “20*20” arrays located at lower-right corners of the plurality of micro light-emitting devices 01 are detected by the detection device, respectively, to finish detection for the entire micro light-emitting devices 01.

In one embodiment, as shown in FIG. 1, a gap 06 is defined between the first detection electrode 201 and the second detection electrode 202 of each of the plurality of detection portions 200 to insulate the first detection electrode 201 and the second detection electrode 202 of each of the plurality of detection portions 200.

It can be understood that the first voltage and the second voltage having different values are transmitted to the first electrode 011 and the second electrode 012 of the corresponding micro light-emitting device 01 by the first detection electrode 201 and the second detection electrode 202 of each of the plurality of detection portions 200, respectively. The gap 06 is located between the first detection electrode 201 and the second detection electrode 202 of each of the detection portions 200. That is, the first detection electrode 201 and the second detection electrode 202 of each of the detection portions 200 are disconnected, so that the first voltage and the second voltage applied only to the corresponding first detection electrode 201 and the corresponding second detection electrode 202, respectively, will not cause voltages of the first detection electrode 201 and the second detection electrode 202 to interfere with each other.

In one embodiment, as shown in FIG. 3, a barrier 203 is disposed in the gap 06 to insulate the first detection electrode 201 and second detection electrode 202 of each of the plurality of detection portions 200.

Wherein, the barrier 203 is composed of an insulation material. Specifically, a constituent material of the barrier 203 may include at least one material of silicon-nitride or silicon-oxide. It can be understood that a width of the barrier 203 may be less than or equal to a width of the gap 06 to prevent reducing effective conductive areas of the first detection electrode 201 and the second detection electrode 202.

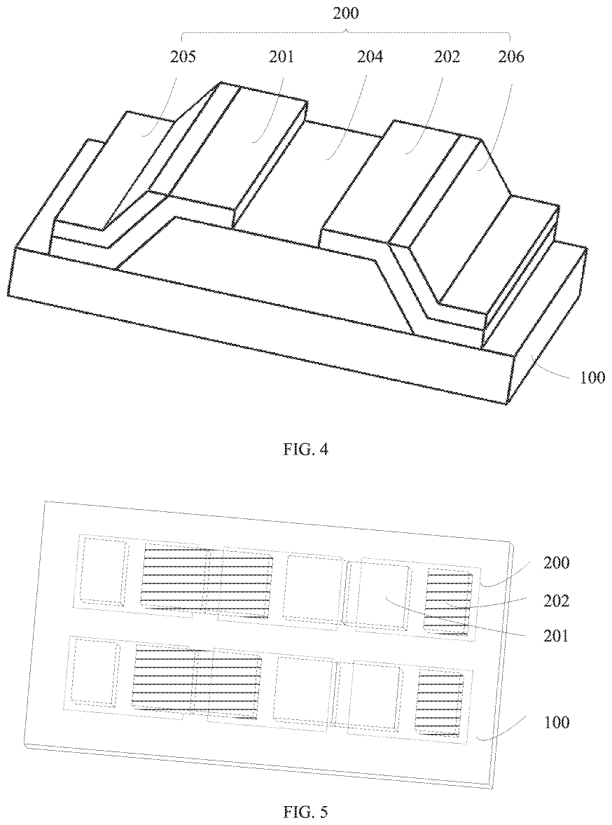

In one embodiment, as shown in FIG. 4, each of the plurality of the detection portions 200 further includes a pad 204. The pad 204 is disposed between the substrate 100 and a corresponding first detection electrode 201 and disposed between the substrate 100 and a corresponding second detection electrode 202 to raise height of the corresponding first detection electrode 201 and the corresponding second detection electrode 202.

Wherein, the pad 204 may be shaped as, but not limited to, a trapezoid, a rectangle, or a semicircle along a longitudinal section of the figures. It only needs to ensure that the pad 204 is protruded from one side of the substrate 100 close to the plurality of micro light-emitting devices 01. Further, a constituent material of the pad 204 may be a transparent elastic material. In one aspect, the pad 204 may raise height of the first detection electrode 201 and the second detection electrode 202 to facilitate the first detection electrode 201 and the second detection electrode 202 to contact the first electrode 011 and the second electrode 012, respectively. In another aspect, in order to ensure that the first detection electrode 201 and the second detection electrode 202 are in contact with the first electrode 011 and the second electrode 012, respectively, the plurality of detection portions 200 are disposed close to the plurality of micro light-emitting devices 01 in general, so that there are certain pressures between the first detection electrode 201 and the second detection electrode 202 and the first electrode 011 and the second electrode 012, respectively, and the pad 204 made of the elastic material may buffer the pressures to prevent damaging the plurality of detection portions 200 or the plurality of micro light-emitting devices 01. Similarly, when the optical component 400 is disposed at one side of the substrate 100 away from the plurality of micro light-emitting devices 01, light emitted by the plurality of micro light-emitting devices 01 may sequentially pass through the substrate 100, the pad 204, the first detection electrode 201, and the second detection electrode 202 to facilitate the optical component 400 to detect.

In one embodiment, as shown in FIG. 4, each of the plurality of detection portions 200 further includes: a first insulation portion 205, disposed in a first insulation area on the corresponding first detection electrode 201 and located away from the corresponding second detection electrode 202; and a second insulation portion 206, disposed in a second insulation area on the corresponding second detection electrode 202 and located away from the corresponding first detection electrode 201.

It can be understood that the first insulation area of the first detection electrode 201 is covered by a corresponding first insulation portion 205, and the second insulation area of the second detection electrode 202 is covered by a corresponding second insulation portion 206. It may ensure that the first insulation area not in contact with the corresponding first electrode 011 in the first detection electrode 201 and the second insulation area not in contact with the corresponding second electrode 012 in the second detection electrode 202 are not in contact with other outside conductive media to further prevent the occurrence of short circuit between the first detection electrode 201 and the second detection electrode 202. Further, one side of the corresponding first detection electrode away from the corresponding second detection electrode may be further covered by the first insulation portion 205, and one side of the corresponding second detection electrode away from the corresponding first detection electrode may be further covered by the second insulation portion 206. It prevents the occurrence of short circuits between two adjacent first detection electrodes and between two adjacent first detection electrodes.

Wherein, constituent materials of the first insulation portion 205 and the second insulation portion 206 may refer to the constituent material of the barrier 203 described above.

In one embodiment, as shown in FIG. 5, the first detection electrodes 201 and the second detection electrodes 202 of two adjacent detection portions 200 located in a same row of the plurality of detection portions are arranged in reverse order, two first detection electrodes 201 close to each other are integrally formed in the two adjacent detection portions 200 located in the same row of the plurality of detection portions 200, and two second detection electrodes 202 close to each other are integrally formed in the two adjacent detection portions 200 located in the same row of the plurality of detection portions 200.

It can be understood that since the first detection electrodes 201 and the second detection electrodes 202 of two adjacent detection portions 200 located in the same row of the plurality of detection portions are arranged in reverse order, the first insulation portions 205 are unnecessary to be disposed in the first insulation areas on two first detection electrodes 201 close to each other in two adjacent detection portions 200 located in the same row of the plurality of detection portions 200, and the second insulation portions 206 are unnecessary to be disposed in the second insulation areas on two second detection electrodes 202 close to each other in two adjacent detection portions 200 located in the same row of the plurality of detection portions 200. Two first detection electrodes 201 close to each other in two adjacent detection portions 200 located in the same row have the first voltage, and two second detection electrodes 202 close to each other in two adjacent detection portions 200 located in the same row have the second voltage, that is, there are no voltage differences, and it will not cause a short-circuit problem.

It needs to be noted that for example, since two first detection electrodes 201 close to each other are integrally formed in the two adjacent detection portions 200 located in the same row of the plurality of detection portions 200, if a short circuit occurs inside the micro light-emitting device 01 corresponding to the detection portion 200 located at a left side, the first detection electrode 201 located at the left side may be applied with the second voltage, thereby causing a voltage of the first detection electrode 201 located at a right side to become the second voltage. This results in no voltage difference between the first detection electrode 201 and the second detection electrode 202 of the detection portion 200 located at the right side, and causes light to not be emitted by the micro light-emitting device 01 corresponding to the detection portion 200 located at the right side, and functions of the detection portion 200 located at the right side may be misjudged as abnormal. That is, by adopting the arrangement of the plurality of detection portions 200 according to the present embodiment, it is necessary to perform tests separately in the next step for two adjacent non-luminous detection portions located in the same row.

The present invention provides a detection method configured to perform electroluminescence detection on a plurality of micro light-emitting devices, and each of the plurality of micro light-emitting devices includes a first electrode and a second electrode disposed at a same side. The method includes, but is not limited to, following embodiments.

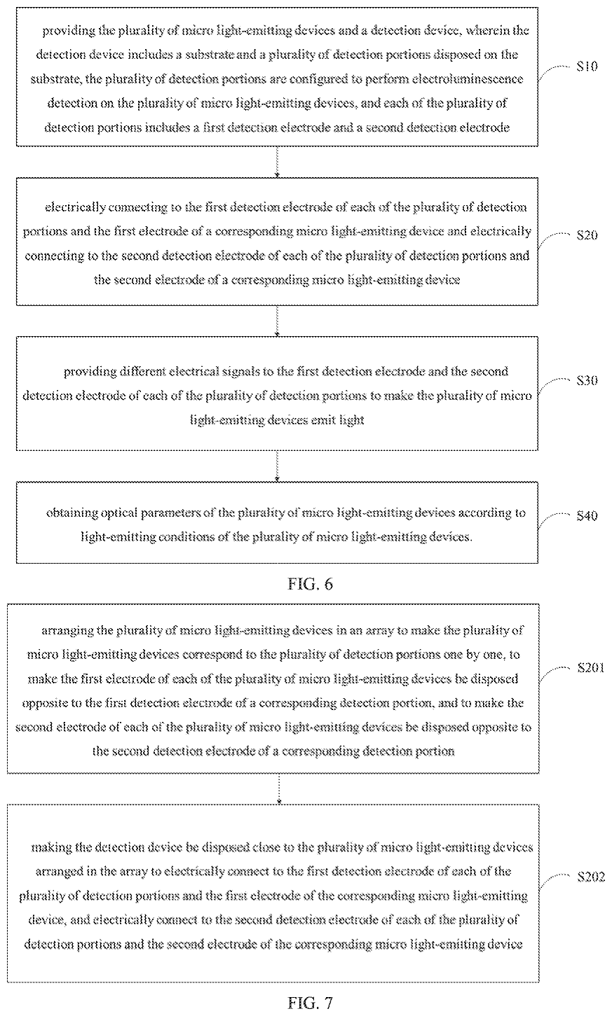

In one embodiment, as shown in FIG. 6, the method may include steps of:

S10: providing the plurality of micro light-emitting devices and a detection device. The detection device includes a substrate and a plurality of detection portions disposed on the substrate. The plurality of detection portions are configured to perform electroluminescence detection on the plurality of micro light-emitting devices, and each of the plurality of detection portions includes a first detection electrode and a second detection electrode.

Specifically, each of the micro light-emitting devices further includes an epitaxial layer disposed at one side of the first electrode and the second electrode, wherein constituent materials of the first electrode and the second electrode may include a p-type doped phosphor material and an n-type doped phosphor material, respectively, and a constituent material of the epitaxial layer 013 may include nitrogen-gallium.

In one embodiment, a constituent material of the substrate may be a transparent material. For example, the substrate may be composed of a transparent glass, or the constituent material of the substrate may be a colorless material.

Based on this, transparent conductive materials may be constituent materials of the first detection electrode and the second detection electrode. For example, essence of the first detection electrode and the second detection electrode may be a strip electrode made of indium-tin-oxide.

It can be understood that the plurality of detection portions of the detection device correspond to the plurality of micro light-emitting devices one by one in number, that is, each of the detection portions detects a corresponding micro light-emitting device. When there are voltage differences between the first electrodes and the second electrodes of the micro light-emitting devices, the working-normally micro light-emitting devices will simultaneously emit light that meets optical conditions at the same time. That is, it may detect whether functions of the plurality of micro light-emitting devices are normal through light-emitting conditions of the plurality of micro light-emitting devices at one time. Moreover, each of the detection portions of the detection device is electrically connected to the corresponding micro light-emitting device to ensure that each of the micro light-emitting devices is only electrically connected to one detection portion, and ensure detection results are also accurate.

S20: electrically connecting the first detection electrode of each of the plurality of detection portions to the first electrode of a corresponding micro light-emitting device, and electrically connecting the second detection electrode of each of the plurality of detection portions to the second electrode of the corresponding micro light-emitting device.

In one embodiment, when the plurality of detection portions perform electroluminescence detection on the plurality of micro light-emitting devices, the first detection electrode of each of the plurality of detection portions may be electrically connected to the first electrode of the corresponding micro light-emitting device by a third wire, and the second detection electrode of each of the plurality of detection portions may be electrically connected to the second electrode of the corresponding micro light-emitting device by a fourth wire.

In one embodiment, as shown in FIG. 7, the step S20 may include steps of:

S201: arranging the plurality of micro light-emitting devices in an array to make the plurality of micro light-emitting devices correspond to the plurality of detection portions one by one, to make the first electrode of each of the plurality of micro light-emitting devices be disposed opposite to the first detection electrode of a corresponding detection portion, and to make the second electrode of each of the plurality of micro light-emitting devices be disposed opposite to the second detection electrode of the corresponding detection portion.

In particular, the plurality of micro light-emitting devices may be arranged in the array on a base substrate to fix the plurality of micro light-emitting devices to facilitate the plurality of micro light-emitting devices to align with the plurality of detection portions. Specifically, the base substrate 500 may be a transparent base substrate, such as a sapphire base substrate or a plastic base substrate.

It should be noted that when the first detection electrode of each of the plurality of detection portions is disposed opposite to the first electrode of the corresponding micro light-emitting device, the plurality of detection portions of the detection device do not need to correspond to the plurality of micro light-emitting devices one by one in number, and the number of the plurality of detection portions may be less than the number of the plurality of micro light-emitting devices. For example, when the plurality of micro light-emitting device are arranged in “40*40” arrays, the plurality of detection portions may be arranged in “20*20” arrays, and “20*20” arrays located at upper-left corners, “20*20” arrays located at upper-right corners, “20*20” arrays located at lower-left corners, and “20*20” arrays located at lower-right corners of the plurality of micro light-emitting devices are detected by the detection device, respectively, to finish detection for the entire micro light-emitting devices.

S202: making the detection device be disposed close to the plurality of micro light-emitting devices arranged in the array to electrically connect the first detection electrode of each of the plurality of detection portions to the first electrode of the corresponding micro light-emitting device, and electrically connect the second detection electrode of each of the plurality of detection portions to the second electrode of the corresponding micro light-emitting device.

Further, it may make certain pressures exist between the first detection electrode and the second detection electrode of each of the detection portions and the first electrode and the second electrode of the corresponding micro light-emitting device, respectively, to ensure complete electrical connection. Accordingly, the third wire and the fourth wire can be omitted, and a risk of disconnection between the first detection electrode and the second detection electrode and the corresponding first electrode and second electrode is reduced, respectively.

In one embodiment, each of the plurality of the detection portions further includes a pad disposed between the substrate and the corresponding first detection electrode, and disposed between the substrate and the corresponding second detection electrode to raise height of the corresponding first detection electrode and the corresponding second detection electrode.

Wherein, the pad may be shaped as, but not limited to, a trapezoid, a rectangle, or a semicircle along a longitudinal section of the figures. It only needs to ensure that the pad is protruded from one side of the substrate close to the plurality of micro light-emitting devices. Further, a constituent material of the pad may be a transparent elastic material. In one aspect, the pad may raise height of the first detection electrode and the second detection electrode to facilitate the first detection electrode and the second detection electrode to contact to the first electrode and the second electrode, respectively. In another aspect, in order to ensure that the first detection electrode and the second detection electrode are in contact with the first electrode and the second electrode, respectively, when the plurality of detection portions are disposed close to the plurality of micro light-emitting devices, there are pressures between the first detection electrode and the second detection electrode and the first electrode and the second electrode, respectively, and the pad made of the elastic material may buffer the pressures to prevent damaging the plurality of detection portions or the plurality of micro light-emitting devices.

S30: providing different electrical signals to the first detection electrode and the second detection electrode of each of the plurality of detection portions to make the plurality of micro light-emitting devices emit light.

Wherein, a first wire may be electrically connected to the first detection electrode of each of the plurality of detection portions located in a same row, and a second wire may be electrically connected to the second detection electrode of each of the plurality of detection portions located in a same row. Further, the first detection electrode of each of the plurality of detection portions located in the same row may be electrically connected to the first wire by a corresponding wire, and the second detection electrode of each of the plurality of detection portions located in the same row may be electrically connected to the second wire by a corresponding wire. Accordingly, the number of wires may be reduced to prevent interference between the wires.

Specifically, a first voltage is transmitted to the first electrode of the corresponding micro light-emitting device by the first wire and the third wire in sequence, and a second voltage is transmitted to the second electrode of the corresponding micro light-emitting device by the second wire and the fourth wire in sequence, to make the first electrode and the second electrode of each of the micro light-emitting devices have the first voltage and the second voltage, respectively. It can be understood that when the first electrodes and the second electrodes of the micro light-emitting devices have the first voltage and the second voltage, respectively, electrons and holes recombine to release energy to make the micro light-emitting devices emit light.

In one embodiment, a gap is defined between the first detection electrode and the second detection electrode of each of the plurality of detection portions to insulate the first detection electrode and the second detection electrode of each of the plurality of detection portions.

It can be understood that the first voltage and the second voltage are transmitted by the first detection electrode and the second detection electrode of each of the plurality of detection portions, respectively, and the gap is located between the first detection electrode and the second detection electrode of each of the detection portions. That is, the first detection electrode and the second detection electrode of each of the detection portions are disconnected, so that the first voltage and the second voltage not applied only to the corresponding first detection electrode and the corresponding second detection electrode, respectively, will not cause voltages of the first detection electrode and the second detection electrode to interfere with each other.

In one embodiment, a barrier is disposed in the gap to insulate the first detection electrode and second detection electrodes of each of the plurality of detection portions.

Wherein, the barrier is composed of an insulation material. Specifically, a constituent material of the barrier may include at least one material of silicon-nitride and silicon-oxide. It can be understood that a width of the barrier may be less than or equal to a width of the gap to prevent reducing effective conductive areas of the first detection electrode and the second detection electrode.

In one embodiment, each of the plurality of detection portions further includes: a first insulation portion, disposed in a first insulation area on the corresponding first detection electrode, wherein the first insulation area is located away from the corresponding second detection electrode; and a second insulation portion, disposed in a second insulation area on the corresponding second detection electrode, wherein the second insulation area is located away from the corresponding first detection electrode. It can be understood that the first insulation area of the first detection electrode is covered by a corresponding first insulation portion, and the second insulation area of the second detection electrode is covered by a corresponding second insulation portion. It may ensure that the first insulation area not in contact with the corresponding first electrode in the first detection electrode and the second insulation area not in contact with the corresponding second electrode in the second detection electrode are not in contact with other outside conductive media to further prevent the occurrence of short circuit between the first detection electrode and the second detection electrode. Further, one side of the corresponding first detection electrode away from the corresponding second detection electrode may be further covered by the first insulation portion, and one side of the corresponding second detection electrode away from the corresponding first detection electrode may be further covered by the second insulation portion 206. It prevents the occurrence of short circuits between two adjacent first detection electrodes and between two adjacent first detection electrodes

Wherein, constituent materials of the first insulation portion and the second insulation portion may refer to the constituent material of the barrier described above.

In one embodiment, the first detection electrodes and the second detection electrodes of two adjacent detection portions located in a same row of the plurality of detection portions are arranged in reverse order, two first detection electrodes close to each other are integrally formed in the two adjacent detection portions located in a same row of the plurality of detection portions, and two second detection electrodes close to each other are integrally formed in the two adjacent detection portions located in a same row of the plurality of detection portions.

It can be understood that since the first detection electrodes and the second detection electrodes of two adjacent detection portions located in the same row of the plurality of detection portions are arranged in reverse order, the first insulation portions are unnecessary to be disposed in the first insulation areas on two first detection electrodes close to each other in two adjacent detection portions located in the same row of the plurality of detection portions, and the second insulation portions are unnecessary to be disposed in the second insulation areas on two second detection electrodes close to each other in two adjacent detection portions located in the same row of the plurality of detection portions. Two first detection electrodes close to each other in two adjacent detection portions located in the same row have the first voltage, and two second detection electrodes close to each other in two adjacent detection portions located in the same row have the second voltage, that is, there are no voltage differences, and it will not cause a short circuit problem.

It needs to be noted that for example, since two first detection electrodes close to each other are integrally formed in the two adjacent detection portions located in the same row of the plurality of detection portions, if a short circuit occurs inside the micro light-emitting device corresponding to the detection portion located at a left side, the first detection electrode located at the left side may be applied with the second voltage, thereby causing a voltage of the first detection electrode located at a right side to become the second voltage. It results in no voltage difference between the first detection electrode and the second detection electrode of the detection portion located at the right side, and causes light to not be emitted by the micro light-emitting device corresponding to the detection portion located at the right side, and functions of the detection portion located at the right side may be misjudged as abnormal. That is, by adopting the arrangement of the plurality of detection portions according to the present embodiment, it is necessary to perform tests separately in the next step for two adjacent non-luminous detection portions located in the same row.

S40: obtaining optical parameters of the plurality of micro light-emitting devices according to light-emitting conditions of the plurality of micro light-emitting devices.

Wherein, the optical parameters may be parameters such as brightness of light or wavelength of light.

It can be understood that when a transparent material may be a constituent material of the substrate, light emitted by the plurality of micro light-emitting devices may pass through the substrate to obtain the optical parameters of the plurality of micro light-emitting devices from one side of the substrate away from the plurality of micro light-emitting devices. Further, when transparent conductive materials may be constituent materials of the first detection electrode and the second detection electrode, light emitted by the plurality of micro light-emitting devices may sequentially pass through the substrate, the first detection electrode, and the second detection electrode to facilitate the optical parameters of the plurality of micro light-emitting devices to be obtained from one side of the substrate away from the plurality of micro light-emitting devices. Furthermore, a constituent material of the pad may be a transparent elastic material, and light emitted by the plurality of micro light-emitting devices may sequentially pass through the substrate, the pad, the first detection electrode, and the second detection electrode to facilitate the optical parameters of the plurality of micro light-emitting devices to be obtained from one side of the substrate away from the plurality of micro light-emitting devices.

Similarly, when the base substrate is a transparent base substrate, such as a sapphire base substrate or a plastic base substrate, on this basis, light emitted by the plurality of micro light-emitting devices may pass through the base substrate to facilitate the optical parameters of the plurality of micro light-emitting devices to be obtained from one side of the substrate away from the plurality of micro light-emitting devices.

The detection device and the detection method are provided by the embodiments of the present application. The detection portion includes the first detection electrode and the second detection electrode disposed at the same side. Different electrical signals are provided to the first detection electrode and the second detection electrode of each of the detection portions by the signal generator. The first detection electrode and the second detection electrode of each of the detection portions are electrically connected to the first electrode and the second electrode of the corresponding micro light-emitting device, respectively, to make the plurality of micro light-emitting devices emit light, and corresponding optical parameters are obtained by the optical component according to light-emitting conditions of the plurality of micro light-emitting devices. In the present solution, the first detection electrode and the second detection electrode of each of the detection portions in the detection device are electrically connected to the first electrode and the second electrode of the corresponding micro light-emitting device, respectively, and electroluminescence detection may be accurately performed on the plurality of micro light-emitting devices at one time by the detection device to improve rate and accuracy of electroluminescence detection performed on the plurality of micro light-emitting devices.

The detection devices and the detection method provided by the embodiments of the present application are described in detail above. Specific examples are applied in the context to explain principles and implementations of the present application. The descriptions of the above embodiments are only used to help understand the technical solutions and core ideas of the present application. Persons skilled in this art should understand that the technical solutions described in the foregoing embodiments can still be modified, or some of the technical features are equivalently replaced. These modifications or replacements do not make essence of essence of corresponding technical solutions to depart from the scope of the technical solutions of the embodiments of the present application.

1. A detection device, configured to perform electroluminescence detection on a plurality of micro light emitting devices, wherein each of the plurality of micro light emitting devices comprises a first electrode and a second electrode disposed at a same side, and the detection device comprises:
a substrate; and
a plurality of detection portions disposed on the substrate and configured to perform electroluminescence detection on the plurality of micro light-emitting devices, wherein each of the plurality of detection portions comprises a first detection electrode and a second detection electrode disposed at a same side, the first detection electrode of each of the plurality of detection portions is disposed opposite to the first electrode of a corresponding micro light-emitting device, the second detection electrode of each of the plurality of detection portions is disposed opposite to the second electrode of a corresponding micro light-emitting device, when the plurality of detection portions perform electroluminescence detection on the plurality of micro light-emitting devices, the first detection electrode of each of the plurality of detection portions is electrically connected to the first electrode of the corresponding micro light-emitting device by contact, the second detection electrode of each of the plurality of detection portions is electrically connected to the second electrode of the corresponding micro light-emitting device by contact, and each of the plurality of detection portions comprises:
a pad disposed between the substrate and a corresponding first detection electrode, and disposed between the substrate and a corresponding second detection electrode, and configured to raise height of the corresponding first detection electrode and the corresponding second detection electrode;
a signal generator providing different electrical signals to the first detection electrode and the second detection electrode of each of the plurality of detection portions when the detection device performs electroluminescence detection on the plurality of micro light-emitting devices, to make the plurality of micro light-emitting devices emit light; and
an optical component located on at least one side of the plurality of micro light-emitting devices and configured to obtain optical parameters of the plurality of micro light-emitting devices according to light-emitting conditions of the plurality of micro light-emitting devices.

2. The detection device as claimed in claim 1, wherein a gap is defined between the first detection electrode and the second detection electrode of each of the plurality detection portions to insulate the first detection electrode and the second detection electrode of each of the plurality of detection portions.

3. The detection device as claimed in claim 2, wherein a barrier is disposed in the gap to insulate the first detection electrode and the second detection electrode of each of the plurality of detection portions.

4. The detection device as claimed in claim 1, wherein each of the plurality of detection portions further comprises:
a first insulation portion disposed in a first insulation area on the corresponding first detection electrode, wherein the first insulation area is located away from the corresponding second detection electrode; and
a second insulation portion disposed in a second insulation area on the corresponding second detection electrode, wherein the second insulation area is located away from the corresponding first detection electrode.

5. The detection device as claimed in claim 1, wherein the first detection electrodes and the second detection electrodes of two adjacent detection portions located in a same row of the plurality of detection portions are arranged in reverse order, two first detection electrodes close to each other are integrally formed in the two adjacent detection portions located in the same row of the plurality of detection portions, and two second detection electrodes close to each other are integrally formed in the two adjacent detection portions located in the same row of the plurality of detection portions.

6. The detection device as claimed in claim 1, wherein a transparent material is a constituent material of the substrate.

7. A detection device, configured to perform electroluminescence detection on a plurality of micro light-emitting devices, wherein each of the plurality of micro light-emitting devices comprises a first electrode and a second electrode disposed at a same side, and the detection device comprises:
a substrate; and
a plurality of detection portions disposed on the substrate and configured to perform electroluminescence detection on the plurality of micro light-emitting devices, wherein each of the plurality of detection portions comprises a first detection electrode and a second detection electrode disposed at a same side, when the plurality of detection portions perform electroluminescence detection on the plurality of micro light-emitting devices, the first detection electrode of each of the plurality of detection portions is electrically connected to the first electrode of a corresponding micro light-emitting device by contact, and the second detection electrode of each of the plurality of detection portions is electrically connected to the second electrode of a corresponding micro light-emitting device by contact;
a signal generator providing different electrical signals to the first detection electrode and the second detection electrode of each of the plurality of detection portions when the detection device performs electroluminescence detection on the plurality of micro light-emitting devices, to make the plurality of micro light-emitting devices emit light; and
an optical component located on at least one side of the plurality of micro light-emitting devices and configured to obtain optical parameters of the plurality of micro light-emitting devices according to light-emitting conditions of the plurality of micro light-emitting devices.

8. The detection device as claimed in claim 7, wherein the first detection electrode of each of the plurality of detection portions is disposed opposite to the first electrode of the corresponding micro light-emitting device, and the second detection electrode of each of the plurality of detection portions is disposed opposite to the second electrode of the corresponding micro light-emitting device.

9. The detection device as claimed in claim 7, wherein a gap is defined between the first detection electrode and the second detection electrode of each of the plurality detection portions to insulate the first detection electrode and the second detection electrode of each of the plurality of detection portions.

10. The detection device as claimed in claim 9, wherein a barrier is disposed in the gap to insulate the first detection electrode and the second detection electrode of each of the plurality of detection portions.

11. The detection device as claimed in claim 7, wherein each of the plurality of detection portions further comprises:
a pad disposed between the substrate and a corresponding first detection electrode, and disposed between the substrate and a corresponding second detection electrode, and configured to raise height of the corresponding first detection electrode and the corresponding second detection electrode.

12. The detection device as claimed in claim 7, wherein each of the plurality of detection portions further comprises:
a first insulation portion disposed in a first insulation area on a corresponding first detection electrode, wherein the first insulation area is located away from a corresponding second detection electrode; and
a second insulation portion disposed in a second insulation area on the corresponding second detection electrode, wherein the second insulation area is located away from the corresponding first detection electrode.

13. The detection device as claimed in claim 7, wherein the first detection electrodes and the second detection electrodes of two adjacent detection portions located in a same row of the plurality of detection portions are arranged in reverse order, two first detection electrodes close to each other are integrally formed in the two adjacent detection portions located in the same row of the plurality of detection portions, and two second detection electrodes close to each other are integrally formed in the two adjacent detection portions located in the same row of the plurality of detection portions.

14. The detection device as claimed in claim 7, wherein a transparent material is a constituent material of the substrate.

15. A detection method, configured to perform electroluminescence detection on a plurality of micro light-emitting devices, wherein each of the plurality of micro light-emitting devices comprises a first electrode and a second electrode disposed at a same side, and the detection method comprises following steps:
providing the plurality of micro light-emitting devices and a detection device, wherein the detection device comprises a substrate and a plurality of detection portions disposed on the substrate, the plurality of detection portions are configured to perform electroluminescence detection on the plurality of micro light-emitting devices, and each of the plurality of detection portions comprises a first detection electrode and a second detection electrode;
electrically connecting the first detection electrode of each of the plurality of detection portions to the first electrode of a corresponding micro light-emitting device, and electrically connecting the second detection electrode of each of the plurality of detection portions to the second electrode of the corresponding micro light-emitting device;
providing different electrical signals to the first detection electrode and the second detection electrode of each of the plurality of detection portions to make the plurality of micro light-emitting devices emit light; and
obtaining optical parameters of the plurality of micro light-emitting devices according to light-emitting conditions of the plurality of micro light-emitting devices.

16. The detection method as claimed in claim 15, wherein the step of electrically connecting the first detection electrode of each of the plurality of detection portions to the first electrode of the corresponding micro light-emitting device and electrically connecting the second detection electrode of each of the plurality of detection portions to the second electrode of the corresponding micro light-emitting device comprises steps of:
arranging the plurality of micro light-emitting devices in an array to make the plurality of micro light-emitting devices correspond to the plurality of detection portions one by one, to make the first electrode of each of the plurality of micro light-emitting devices be disposed opposite to the first detection electrode of a corresponding detection portion, and to make the second electrode of each of the plurality of micro light-emitting devices be disposed opposite to the second detection electrode of the corresponding detection portion; and
making the detection device be disposed close to the plurality of micro light-emitting devices arranged in the array to electrically connect the first detection electrode of each of the plurality of detection portions to the first electrode of the corresponding micro light-emitting device, and electrically connect the second detection electrode of each of the plurality of detection portions to the second electrode of the corresponding micro light-emitting device.
